(19) United States
(12) Patent Application Publication
(10) Pub. No.: US 2026/0182360 A1
(43) Pub. Date: Jun. 25, 2026

(54) CAPACITOR STRUCTURE AND METHOD OF MAKING THEREOF

(71) Applicant: Taiwan Semiconductor Manufacturing Company, Ltd., Hsinchu (TW)

(72) Inventors: Chieh-En Chen, Tainan City (TW); Shyh-Fann Ting, Tainan City (TW)

(21) Appl. No.: 18/986,912

(22) Filed: Dec. 19, 2024

(51) Int. Cl. H01L 23/522; H01L 21/768; H04N 25/616; H04N 25/771; H10D 1/68

(52) U.S. Cl. CPC H10W 20/496; H04N 25/616; H04N 25/771; H10D 1/692; H10W 20/033

(57) ABSTRACT

Some embodiments relate to a three-dimensional (3D) metal-insulator-metal (MIM) capacitor having a first set of conductive rods conductively connected to a first conductive plate, a first set of corresponding conductive sleeves conductively connected to a second conductive plate, and a conductive perimeter and filler enveloping the first set of corresponding conductive sleeves. The conductive perimeter and filler are conductively connected to the first conductive plate. The first conductive plate is electrically isolated from the second conductive plate. For each conductive rod of the first set of conductive rods and corresponding conductive sleeve of the first set of corresponding conductive sleeves, the conductive rod is laterally enveloped by the corresponding conductive sleeve, and the conductive rod is electrically isolated from the corresponding conductive sleeve by a dielectric barrier. The first set of conductive sleeves is electrically isolated from the conductive perimeter and filler by the dielectric barrier.

### BACKGROUND

Many electronic devices, such as, for example, cameras, mobile telephones, laptops, and computers, include integrated-circuit (IC) image sensors. Image sensors may use arrays of pixel elements to convert incident light into electric signals that are then used to generate corresponding digital images. A typical pixel element includes a photodiode, a capacitor, and a set of transistors. The IC image sensors may be manufactured using, for example, complementary metal-oxide-semiconductor (CMOS) technology, generating CMOS image sensors (CIS).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified cross-sectional view of an example segment of an IC image sensor, including an example 3D MIM capacitor in accordance with some embodiments of the disclosure.

FIG. 1A illustrates an enlargement of a section of FIG. 1 to more clearly illustrate certain thin features of the capacitor.

FIG. 2 illustrates a simplified example partial plan view of the capacitor of FIG. 1.

FIG. 3 illustrates an alternative simplified example partial plan view of the capacitor of FIG. 1.

FIG. 4 illustrates an alternative simplified example partial plan view of the capacitor of FIG. 1.

FIG. 5 illustrates a simplified cross-sectional view of an alternative example segment of an IC image sensor, including the example 3D MIM capacitor of FIG. 1.

FIGS. 6A-6Z illustrate simplified cross-sectional views of some stages of an example fabrication process of the 3D MIM capacitor of FIG. 1 in accordance with some embodiments of the disclosure.

FIG. 7 is a flowchart illustrating a method of forming a 3D MIM capacitor in accordance with some embodiments of the disclosure.

FIG. 8 illustrates a simplified cross-sectional view of an alternative example segment of an IC image sensor, including an example 3D MIM capacitor.

FIG. 9 illustrates a corresponding simplified partial plan view of the capacitor of FIG. 8.

FIG. 10 illustrates a simplified partial plan view of an alternative example 3D MIM capacitor.

FIG. 11 illustrates a simplified partial plan view of an alternative example 3D MIM capacitor.

FIG. 12 illustrates a simplified circuit diagram of an example multi-conversion-gain image sensor circuit in accordance with some embodiments of the disclosure.

FIG. 13 illustrates a simplified circuit diagram of an example correlated double sampling (CDS) circuit in accordance with some embodiments of the disclosure.

FIG. 14 illustrates a simplified circuit diagram of an example lateral overflow integration capacitor (LOFIC) circuit.

### DETAILED DESCRIPTION

The following disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees, 180 degrees, or at other orientations) and the spatially relative descriptors used herein may likewise be interpreted accordingly.

Moreover, “first”, “second”, “third”, etc. may be used herein for ease of description to distinguish between different elements of a figure or a series of figures. “first”, “second”, “third”, etc. are not intended to be descriptive of the corresponding element, but rather are merely generic identifiers. For example, “a first dielectric layer” described in connection with a first figure may not necessarily correspond to a “first dielectric layer” described in connection with some embodiments, but rather may correspond to a “second dielectric layer” in other embodiments.

CMOS image sensors comprise arrays of pixel elements. Along with photodiode and transistor elements, a pixel element of a CMOS image sensor typically includes one or more capacitors such as, for example, a charge-collecting capacitor for collecting charges generated by a corresponding photodetector from the absorption of incident photons. In some image sensors, a set of two or more pixel elements may share a common charge-collecting capacitor. Some images sensors may use capacitors for other purposes, as described below. Different image-sensing application may benefit from having different and/or multiple levels of capacitance. An image sensor used for high dynamic range (HDR) image-sensing applications, for example, may benefit from having multiple levels of capacitance. Additionally, regardless of the desired levels of capacitance, it is generally advantageous to maximize capacitance per volume of space in the image sensor. For example, it would be beneficial for an IC image sensor to have a capacitor that minimizes the plan-view, or footprint, area used to provide a given capacitance.

A metal-insulator-metal (MIM) capacitor is an IC capacitor disposed within the interlayer dielectric (ILD) and metallization layers of the back-end-of-line (BEOL) stack of an IC device. Note that ILD may also be referred to as inter-metal dielectric (IMD). A MIM capacitor has a top electrode, or conductive feature, and a bottom electrode—where top and bottom are relative to the substrate-separated by a high-k dielectric barrier. The top electrode may be referred to as a capacitor top metal (CTM) and the bottom electrode may be referred to as a capacitor bottom metal (CBM).

In a two-dimensional (2D) MIM capacitor, these electrodes are planar plates. In a three-dimensional (3D) MIM capacitor, however, these electrodes may be complementary crenelated, corrugated, or ridged shapes, or otherwise varying in the height dimension. Consequently, all else being equal, a 3D MIM capacitor would have a larger capacitance than a 2D MIM capacitor having the same footprint.

A typical 3D MIM capacitor is formed by a process that includes etching a cavity in ILD, depositing a conductive layer to form the CBM, then depositing a high-k dielectric barrier layer over the CBM, then depositing another conductive layer to form the CTM, and then filling the remainder of the cavity with ILD or similar dielectric material, which helps provide structural support to the capacitor. In some embodiments of the present disclosure, a 3D MIM capacitor is formed using multiple conductive layers for the CBM, conductive plugs and/or rods for the CTM, and no structural-support dielectric within the capacitor. This structure provides an increased density of CBM and CTM surfaces in the area of the 3D MIM capacitor, thereby providing greater capacitance per unit of area. In addition, in some embodiments, the capacitor may be multifurcated into capacitive subsegments for providing enhanced features to the corresponding image sensor.

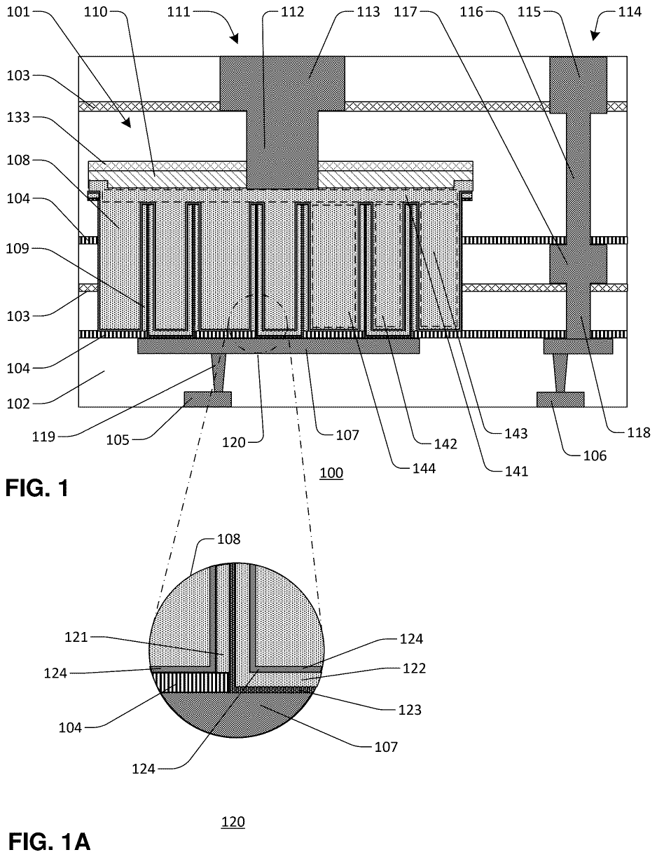

FIG. 1 illustrates a simplified cross-sectional view of an example segment 100 of an IC image sensor, including an example 3D MIM capacitor 101 in accordance with some embodiments of the disclosure. The capacitor 101 is formed in the BEOL stack of the IC, characterized by, for example, ILD layers 102, etch-stop layers 103, barrier layers 104, and metallization layer routing lines such as metallic interconnects 105 and 106. The ILD 102 may comprise, for example, silicon dioxide (SiO₂) or any other suitable dielectric (e.g., silicon nitride, carbon doped silicon dioxide, silicon oxynitride, borosilicate glass (BSG), phosphorus silicate glass (PSG), borophosphosilicate glass (BPSG), fluorosilicate glass (FSG), undoped silicate glass (USG), a porous dielectric material, or the like). The etch-stop layers 103 may comprise, for example, silicon nitride (Si₃N₄, sometimes abbreviated as SiN) or any other suitable dielectric (e.g., silicon carbide (SiC)). The barrier layers 104 may help prevent metal (e.g., copper) extrusion of adjacent metal features and may comprise, for example, silicon carbide (SiC) or any other suitable dielectric (e.g., silicon oxynitride or silicon oxycarbide). The metallic interconnects 105 and 106 may comprise, for example, copper or any other suitable conductor (e.g., aluminum, tungsten, or ruthenium).

FIG. 1A illustrates an enlargement of a section 120 of FIG. 1 to more clearly illustrate certain thin features of the capacitor 101. The capacitor 101 comprises a top electrode 108, which may be referred to as the CTM, and a bottom electrode 109, which may be referred to as the CBM. The top electrode 108, although uniform in composition, may be said to comprise a plurality of segments such as, a conductive plate 141, a set of conductive rods such as conductive rod 142, a perimeter 143, and an interstitial filler 144. The top electrode 108 is separated from the bottom electrode 109 by a dielectric barrier 124. The dielectric barrier 124 may be a high-k dielectric such as, for example, aluminum oxide (Al₂O₃), hafnium oxide (HfO₂), silicon dioxide (SiO₂), silicon carbide (SiC), silicon mononitride (SiN), silicon nitride (Si₃N₄), tantalum nitride (Ta₂O₅), tantalum oxynitride (TaON), titanium oxide (TiO₂), zirconium oxide (ZrO₂), and/or any other suitable dielectric.

The bottom electrode 109 comprises a first layer 121 and a second layer 122 of conductive material, which together may be said to form conductive sleeves that envelop the conductive rods 142 of the top electrode 108. The first layer 121 may be said to form an outer section of the conductive sleeve, while the second layer 122 may be said to form an inner section of the conductive sleeve. The conductive material of the top electrode 108 and of the layers 121 and 122 of the bottom electrode 109 may be, for example, titanium nitride (TiN). The second layer 122 is conductively connected to a conductive plate 107 via a conductive diffusion barrier 123. Specifically, a bottom section of the second layer 122, which may be referred to as a bottom section of the inner section of the conductive sleeve, is conductively connected to the conductive plate 107 via the conductive diffusion barrier 123. The conductive plate 107 may be a feature of the corresponding metallization layer of the BEOL stack and may comprise, for example, copper. The conductive diffusion barrier 123 prevents diffusion of copper from the conductive plate 107. The conductive diffusion barrier 123 may comprise a combination of tantalum and tantalum nitride (Ta/TaN). In some implementations, the conductive diffusion barrier 123 may comprise tantalum and tantalum nitride in relative ratios in the range of approximately 3:1 to 3:6 or other similar values. The conductive diffusion barrier 123 may also separate the first layer 121 from adjoining sections of the second layer 122. Note that, in some alternative embodiments (not shown), adjoining sections of the first layer 121 and the second layer 122 may be in direct contact without an intervening diffusion barrier layer.

The first layer 121 is separated from the conductive plate 107 by a barrier layer 104. The conductive plate 107 may connect to other components of the image sensor through vias such as via 119 and interconnects such as interconnect 105 of a lower metallization layer. The capacitor 101 provides a relatively dense array of adjoining top electrode 108 and bottom electrode 109 surfaces, thereby providing a relatively high capacitance for the given footprint. The density of the array is also such that there is no need for structural support dielectric material within the capacitor 101, which is free of dielectric support structures.

In some implementations, the first layer 121 and the second layer 122 may each have a thickness range of between approximately 100 and 1000 Angstroms (Å) or other similar values. The conductive barrier 123 may have a thickness range of between approximately 50 Å and 800 Å or other similar values. The dielectric barrier 124 may have a thickness range of between approximately 50 Å and 200 Å or other similar values. The conductive rods 142 of the top electrode 108 and corresponding conductive sleeves of the bottom electrode 109 may have a height range of between approximately 5000 Å and 20000 Å or other similar values. The height to width aspect ratio of a rod 142 may be in the range of between approximately 5:1 to 50:1 or other similar values.

The top electrode 108 may be topped by an oxide layer 110 and a nitride layer 133, which may form a passivation layer. The oxide layer 110 may comprise, for example, a plasma-enhanced oxide (PEOX). Plasma-enhanced oxide is an oxide (e.g., silicon oxide) deposited with a plasma-enhanced chemical vapor deposition (PE-CVD) process. The nitride layer 133 may comprise, for example, silicon nitride. The top electrode 108 may connect to other components of the image sensor via conductive interconnect 111, which comprises a via section 112 and a trench section 113.

In addition to the capacitor 101, the segment 100 also includes a peripheral interconnect 114, which includes via portions such as, for example, via portions 116 and 118, trench portions such as, for example, trench portions 115 and 117, and routing lines such as, for example, interconnect 106. The interconnect 114 may be formed by, for example, dual damascene processes.

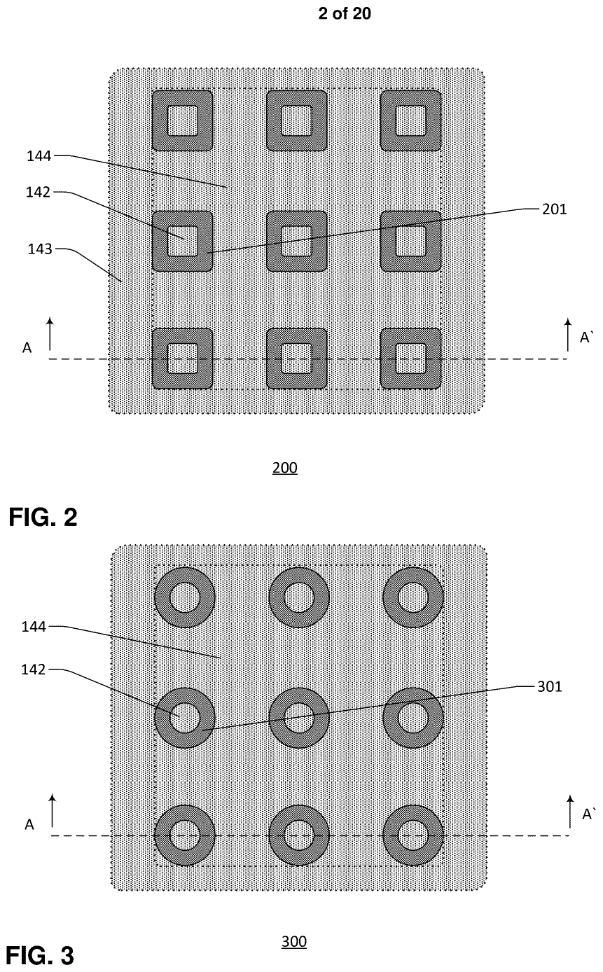

FIG. 2 illustrates a simplified example partial plan view 200 of the capacitor 101 of FIG. 1. The view 200 shows the rods 142 and corresponding sleeves 201 (comprising conductive layers 121 and 122 and conductive diffusion barrier 123) as having rounded-square cross-sections in a plan view. The view 200 also illustrates the perimeter 143 and the interstitial conductive filler 144. In addition, the view 200 illustrates a cut line A-A′ that may correspond to the cross-sectional view of FIG. 1. The example view 200 shows the top electrode 108 comprising a set of nine rods 142 arranged as a 3×3 array. As would be appreciated, alternative implementations may have any suitable number of rods arranged in any suitable arrangement.

FIG. 3 illustrates an alternative simplified example partial plan view 300 of the capacitor 101 of FIG. 1. The view 300 is substantially similar to the view 200 of FIG. 2, except that the rods 142 and the corresponding sleeves 301 (comprising conductive layers 121 and 122 and conductive diffusion barrier 123) have circular cross sections in a plan view.

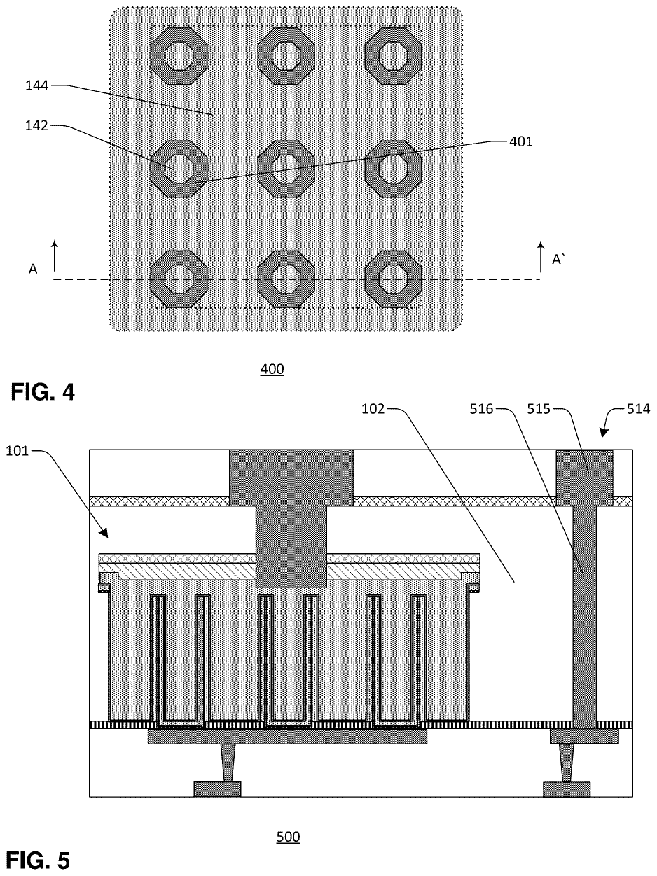

FIG. 4 illustrates an alternative simplified example partial plan view 400 of the capacitor 101 of FIG. 1. The view 400 is substantially similar to the view 200 of FIG. 2 and the view 300 of FIG. 3, except that the rods 142 and the corresponding sleeves 401 (comprising conductive layers 121 and 122 and conductive diffusion barrier 123) have octagonal cross sections in a plan view. As would be appreciated, other alternative embodiments can have any suitable cross-sectional shapes in a plan view for the rods and the corresponding sleeves.

FIG. 5 illustrates a simplified cross-sectional view of an alternative example segment 500 of an IC image sensor, including the example 3D MIM capacitor 101 of FIG. 1. The example segment 500 is substantially similar to the example segment 100 of FIG. 1, except that the capacitor 101 is formed in an additional ILD layer 102, rather than in typical metallization layers. Accordingly, the ILD layer 102 of segment 500 is free of some of the etch-stop 103 and barrier 104 layers of the segment 500. This may be useful for reducing the number of steps for forming peripheral devices such as interconnects. As can be appreciated, the interconnect 514 of segment 500 may be formed in one dual damascene process and comprises just one trench section 515 and one via section 516, as opposed to the multiple corresponding sections for interconnect 114 of segment 100 of FIG. 1. Using an additional ILD layer 102 as in segment 500 may also be useful if multiple similar MIM capacitors are formed in that layer. The capacitor 101 of segment 500 itself is fabricated in substantially the same way as the capacitor 101 of segment 100 of FIG. 1.

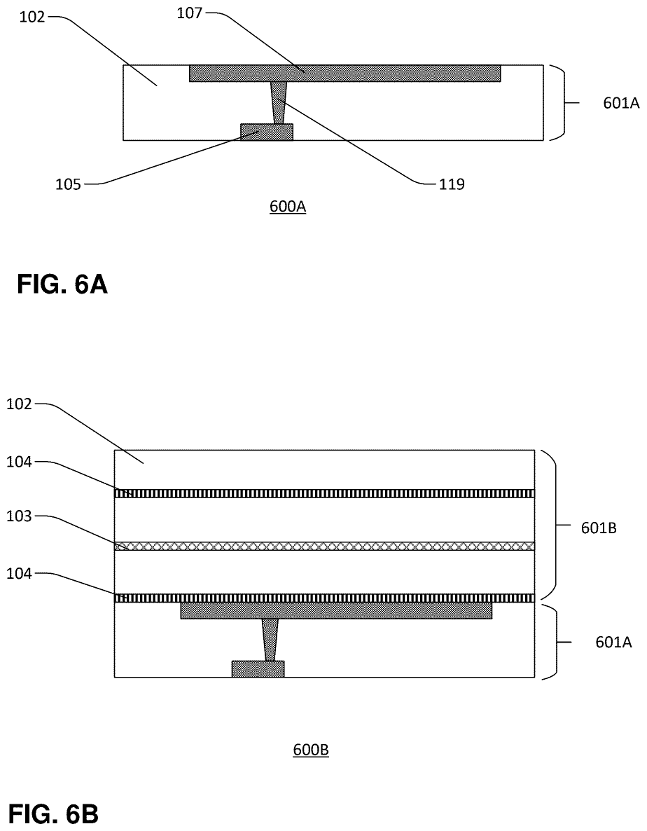

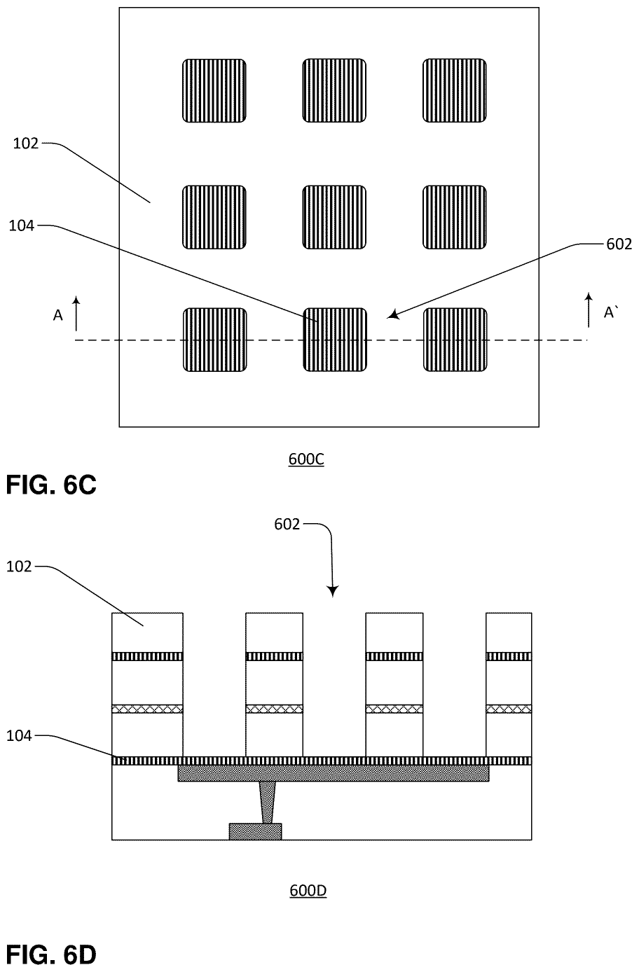

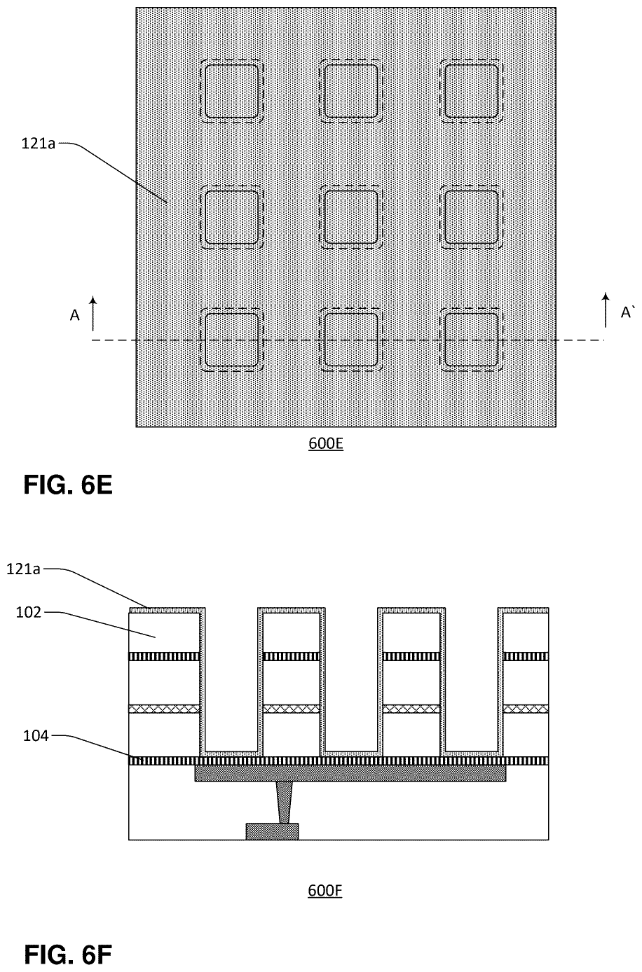

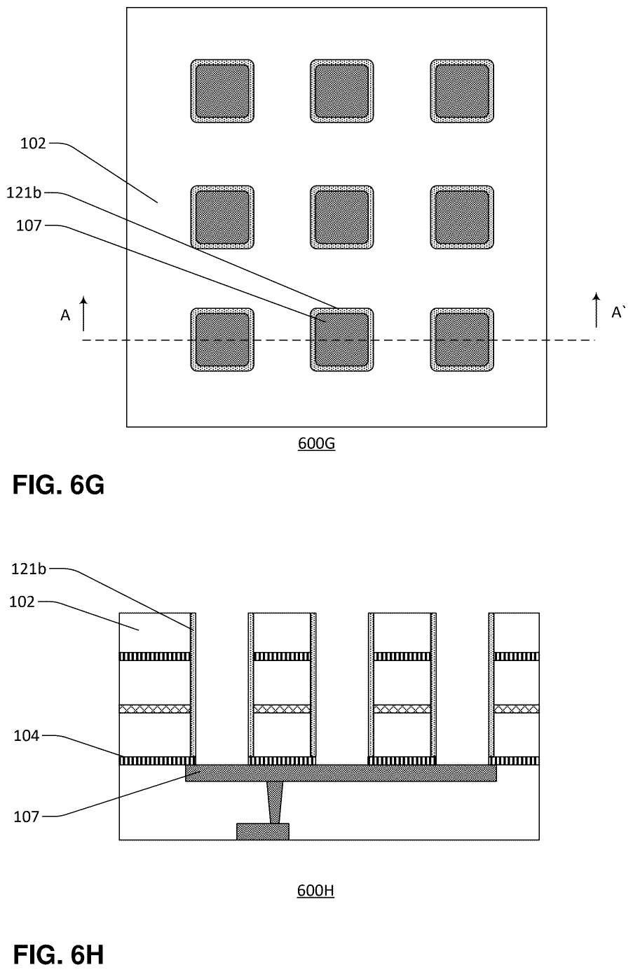

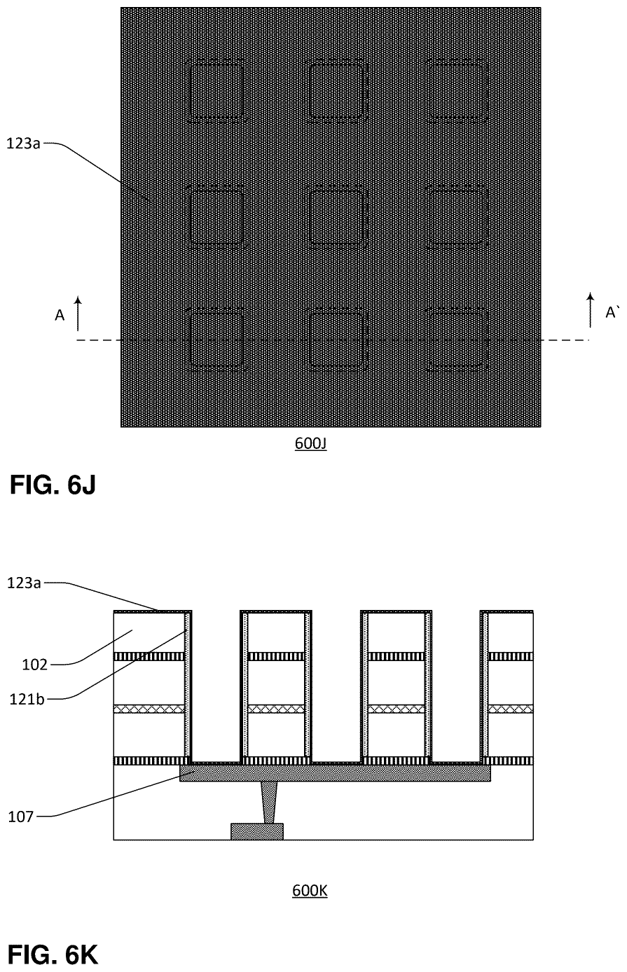

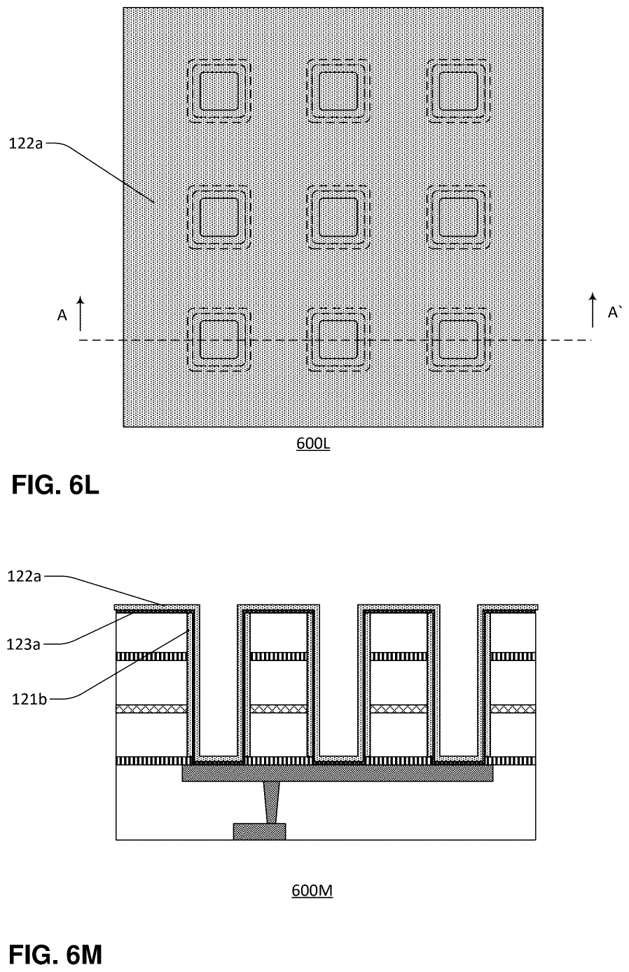

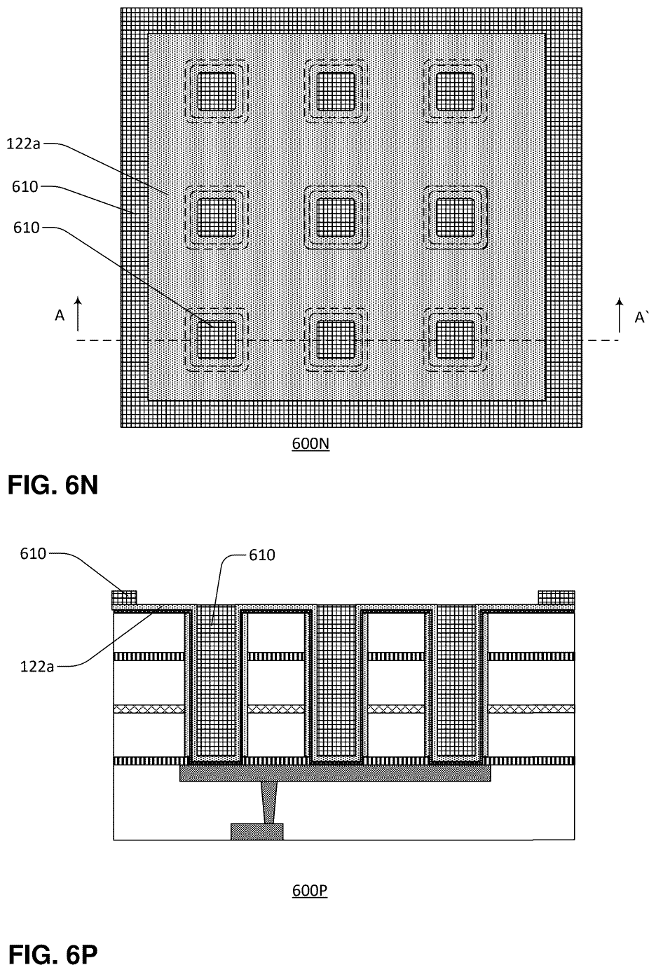

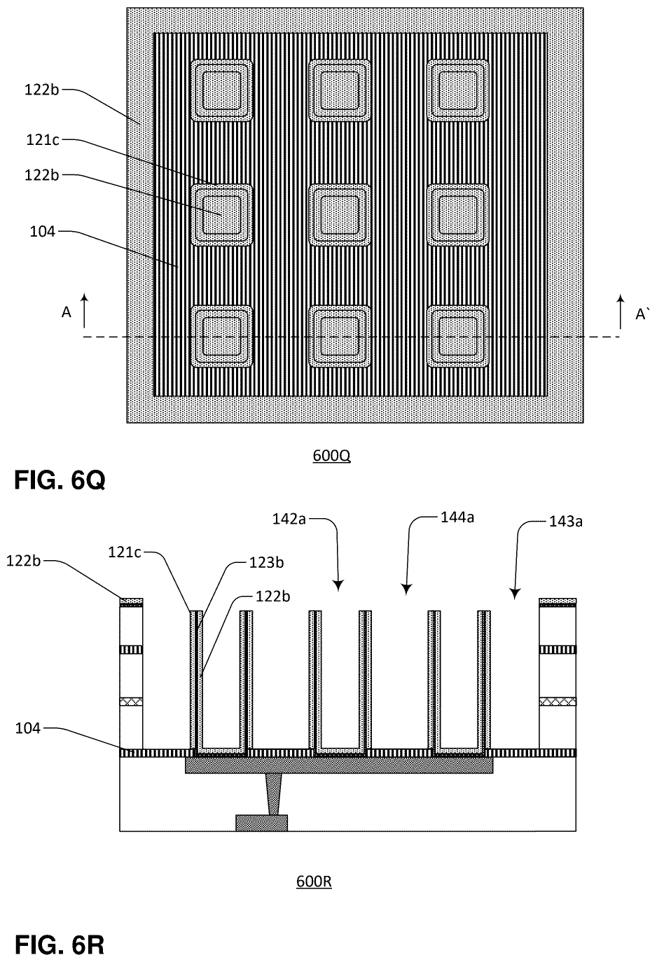

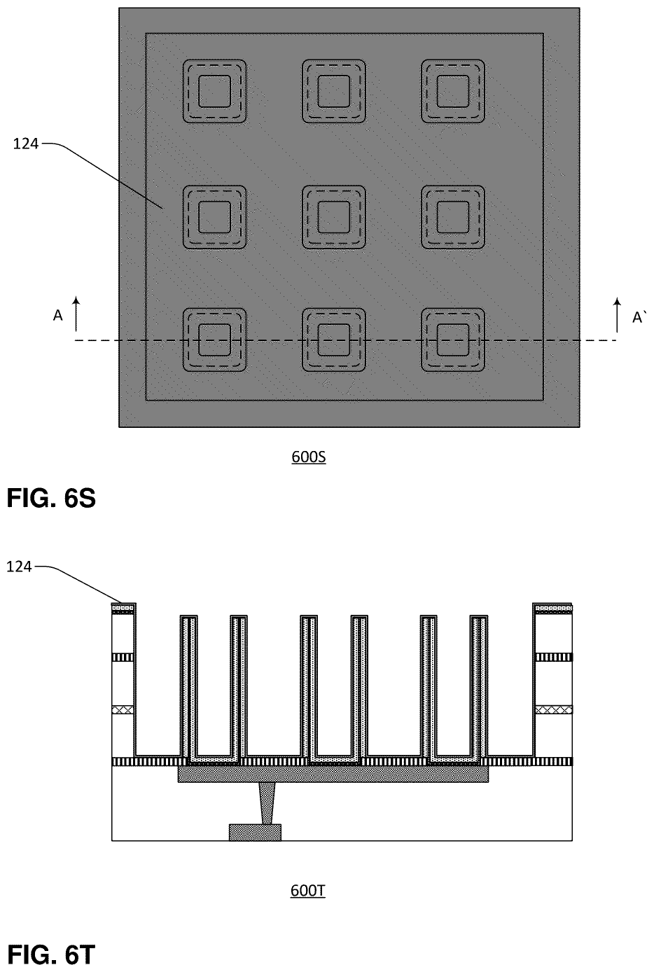

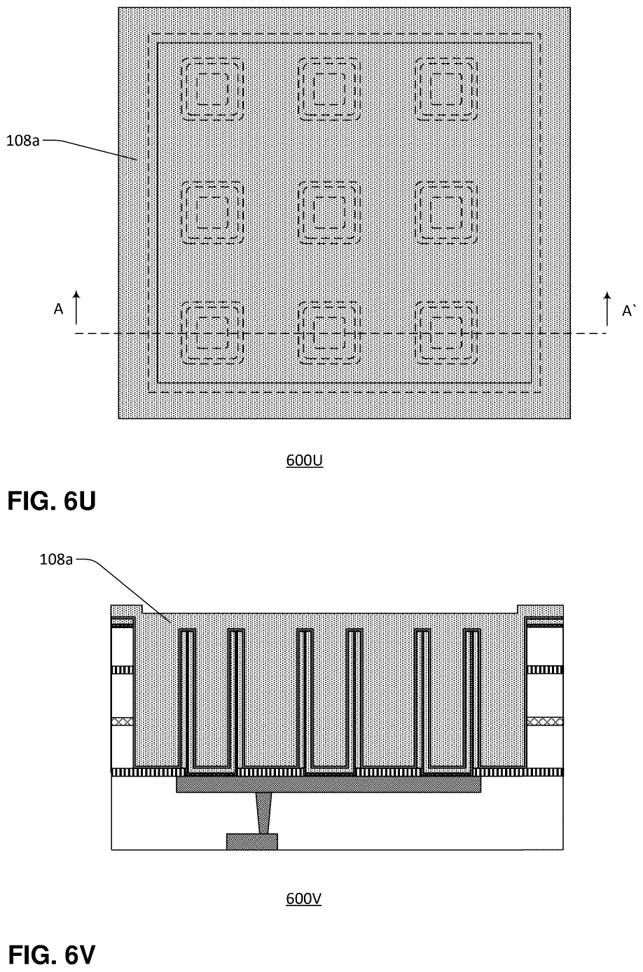

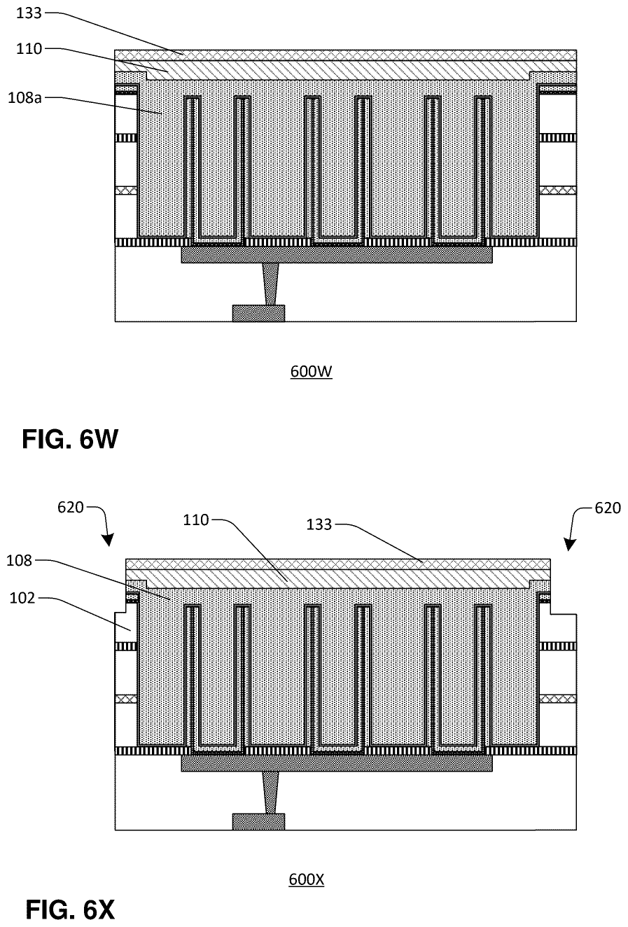

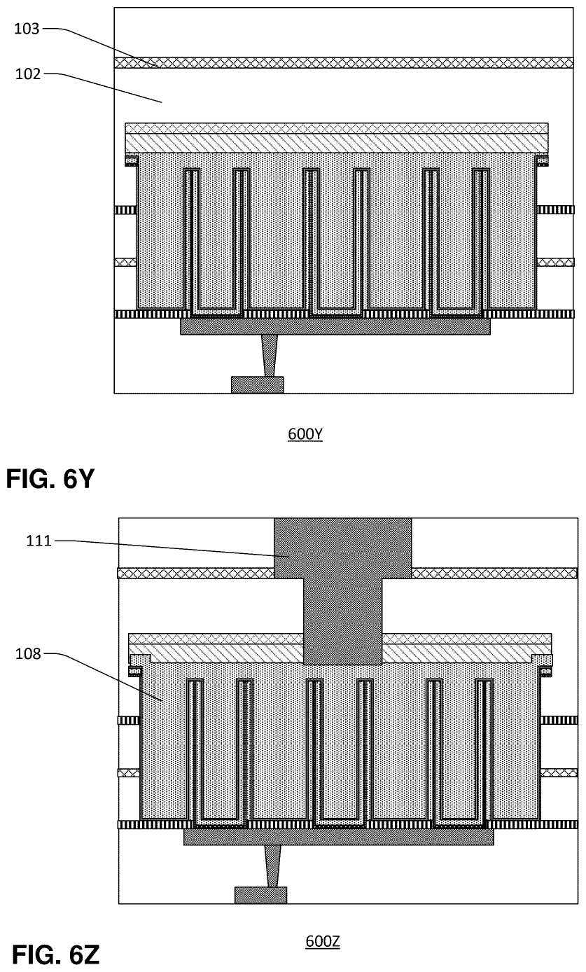

FIGS. 6A-6Z illustrate simplified cross-sectional views of some stages of an example fabrication process of the 3D MIM capacitor 101 of FIG. 1 in accordance with some embodiments of the disclosure. Substantially the same steps may also be used to fabricate the 3D MIM capacitor 101 of FIG. 5. Although FIGS. 6A-6Z are described as a series of acts, it will be appreciated that these acts are not limiting in that the order of the acts can be altered in other embodiments, and the methods disclosed are also applicable to other structures. In some embodiments, alternative steps may be performed instead of the steps described. In some embodiments, some acts that are illustrated and/or described may be omitted in whole or in part. In some embodiment, additional acts that are not described herein may also be performed as part of the manufacturing process.

FIG. 6A illustrates a simplified cross-sectional view of a portion 600A of a wafer comprising a BEOL segment 601A. The BEOL segment 601A is formed over an already fabricated front-end-of-line (FEOL) (not shown), middle-end-of-line (MEOL) stack (not shown), and a portion of the BEOL stack (not shown) such as, for example, lower-level metallization layers (not shown). The portion 600A comprises metallic interconnect 105, via 119 and conductive plate 107 arranged within ILD 102. ILD 102, which may be, for example, SiO₂, may be grown using, for example, chemical vapor deposition (CVD). Metallic features 105, 119, and 107, which may be, for example, Cu, may be formed using, for example, dual damascene processes.

FIG. 6B illustrates a simplified cross-sectional view of a portion 600B, corresponding to the portion 600A of FIG. 6A after the formation of BEOL segment 601B over BEOL segment 601A of FIG. 6A. The BEOL segment 601B is formed by depositing a barrier layer 104, then ILD 102, then an etch-stop layer 103, then more ILD 102, then another barrier layer 104, and then more ILD 102. The depositions may be using, for example, CVD. The barrier layers 104 may be, for example, SiC. The etch-stop layers 103 may be, for example, silicon nitride.

FIG. 6C illustrates a simplified plan view of a portion 600C, corresponding to the portion 600B of FIG. 6B after etching cavities 602, which expose the lower barrier layer 104. FIG. 6D illustrates a simplified cross-sectional view of a portion 600D corresponding to a cross-sectional view of the portion 600C along the cut line A-A′ of FIG. 6C. The etching may be guided by using a patterning layer (not shown). The patterning layer may be a hardened part of a photoresist mask developed using a photolithography process. The patterning layer may alternatively be a hardmask layer formed using photolithographically developed photoresist (not shown) and etching. The etching may be dry etching with, for example, a dry etchant such as, for example, a fluorine-containing gas such as CF₄, a gaseous mixture of xenon and fluoride (e.g., XeF₆), sulfur and fluoride (e.g., SF₆), or some other suitable mixture.

FIG. 6E illustrates a simplified plan view of a portion 600E, corresponding to the portion 600C of FIG. 6C and the portion 600D of FIG. 6D after deposition of a conductive layer 121a, which will be further processed to form part of the lower electrode 109 of FIG. 1. FIG. 6F illustrates a simplified cross-sectional view of a portion 600F corresponding to a cross-sectional view of the portion 600E along the cut line A-A′ of FIG. 6E. The deposition of the conductive layer 121a, which may comprise, for example, TiN, may be performed using, for example, CVD.

FIG. 6G illustrates a simplified plan view of a portion 600G, corresponding to the portion 600E of FIG. 6E and the portion 600F of FIG. 6F after etching away horizontal portions of the conductive layer 121a and portions of the barrier layer 104 to leave conductive layer 121b and expose portions of the conductive plate 107 and the ILD 102. FIG. 6H illustrates a simplified cross-sectional view of a portion 600H corresponding to a cross-sectional view of the portion 600G along the cut line A-A′ of FIG. 6G.

FIG. 6J illustrates a simplified plan view of a portion 600J, corresponding to the portion 600G of FIG. 6G and the portion 600H of FIG. 6H after deposition of a conductive diffusion barrier 123a, which will be further processed to form conductive diffusion barrier 123 of FIG. 1. The conductive diffusion barrier 123a, which may be, for example, Ta/TaN, may be deposited by, for example, CVD. The CVD of the diffusion barrier 123a may be performed in a single CVD step using a corresponding mix of Ta and TaN. FIG. 6K illustrates a simplified cross-sectional view of a portion 600K corresponding to a cross-sectional view of the portion 600J along the cut line A-A′ of FIG. 6J.

FIG. 6L illustrates a simplified plan view of a portion 600L, corresponding to the portion 600J of FIG. 6J and the portion 600K of FIG. 6K after deposition of a conductive layer 122a, which will be further processed to form part of the lower electrode 109 of FIG. 1. FIG. 6M illustrates a simplified cross-sectional view of a portion 600M corresponding to a cross-sectional view of the portion 600L along the cut line A-A′ of FIG. 6L. The deposition of the conductive layer 122a, which may comprise, for example, TiN, may be performed using, for example, CVD.

FIG. 6N illustrates a simplified plan view of a portion 600N, corresponding to the portion 600K of FIG. 6K and the portion 600L of FIG. 6L after developing of photoresist 610 to form a patterning layer, including plugging of cavities in portions 600K and 600L. The photoresist 610 may be developed using a photolithographic process. FIG. 6P illustrates a simplified cross-sectional view of a portion 600P corresponding to a cross-sectional view of the portion 600N along the cut line A-A′ of FIG. 6N.

FIG. 6Q illustrates a simplified plan view of a portion 600Q, corresponding to the portion 600N of FIG. 6N and the portion 600P of FIG. 6P after etching dielectric layers in accordance with the patterning layer of FIG. 6P. The etching exposes the lower barrier layer 104 and may also remove portions of conductive layers 121b, 122a, and 123a to form corresponding conductive layers 121c, 122b, and 123b, respectively. FIG. 6R illustrates a simplified cross-sectional view of a portion 600R corresponding to a cross-sectional view of the portion 600Q along the cut line A-A′ of FIG. 6Q. The etching forms cavities such as, for example, cavities 142a, 143a, and 144a, which, when later filled with conductive material, will form conductive rod 142, conductive perimeter 143, and conductive interstitial filler 144 of the top electrode 108 of FIG. 1.

FIG. 6S illustrates a simplified plan view of a portion 600S, corresponding to the portion 600Q of FIG. 6Q and the portion 600R of FIG. 6R after deposition of a dielectric barrier 124 over the portion 600R. FIG. 6T illustrates a simplified cross-sectional view of a portion 600T corresponding to a cross-sectional view of the portion 600S along the cut line A-A′ of FIG. 6S. The deposition of the dielectric barrier, which may comprise a high-k dielectric, may be performed using, for example, CVD.

FIG. 6U illustrates a simplified plan view of a portion 600U, corresponding to the portion 600S of FIG. 6S and the portion 600T of FIG. 6T after deposition of conductive material 108a over portion 600T, which, following some further processing, will form the top electrode 108 of FIG. 1. FIG. 6V illustrates a simplified cross-sectional view of a portion 600V corresponding to a cross-sectional view of the portion 600U along the cut line A-A′ of FIG. 6U. The deposition of the conductive material 108a, which may comprise TiN, may be performed using, for example, CVD.

FIG. 6W illustrates a simplified cross-sectional view of a portion 600W corresponding to the portion 600V of FIG. 6V, following the deposition of a PEOX layer 110 and a nitride layer 133 over the portion 600V. The depositions may be performed using, for example, CVD.

FIG. 6X illustrates a simplified cross-sectional view of a portion 600X corresponding to the portion 600W of FIG. 6W, following patterning of the conductive material 108a of FIG. 6V to form the top electrode 108 of FIG. 1. The patterning, including the formation of voids 620, may be achieved by using photolithographic processes to generate a patterning layer (not shown) and then etching accordingly.

FIG. 6Y illustrates a simplified cross-sectional view of a portion 600Y corresponding to the portion 600X of FIG. 6X, following deposition of additional ILD 102 and an additional etch-stop layer 103, which may be part of a metallization layer of the BEOL stack of the corresponding IC. The depositions may be performed using, for example, CVD.

FIG. 6Z illustrates a simplified cross-sectional view of a portion 600Z corresponding to the portion 600Y of FIG. 6Y, following the formation of a conductive interconnect 111 to connect to the top electrode 108. The conductive interconnect 111 may be formed using, for example, a dual damascene process.

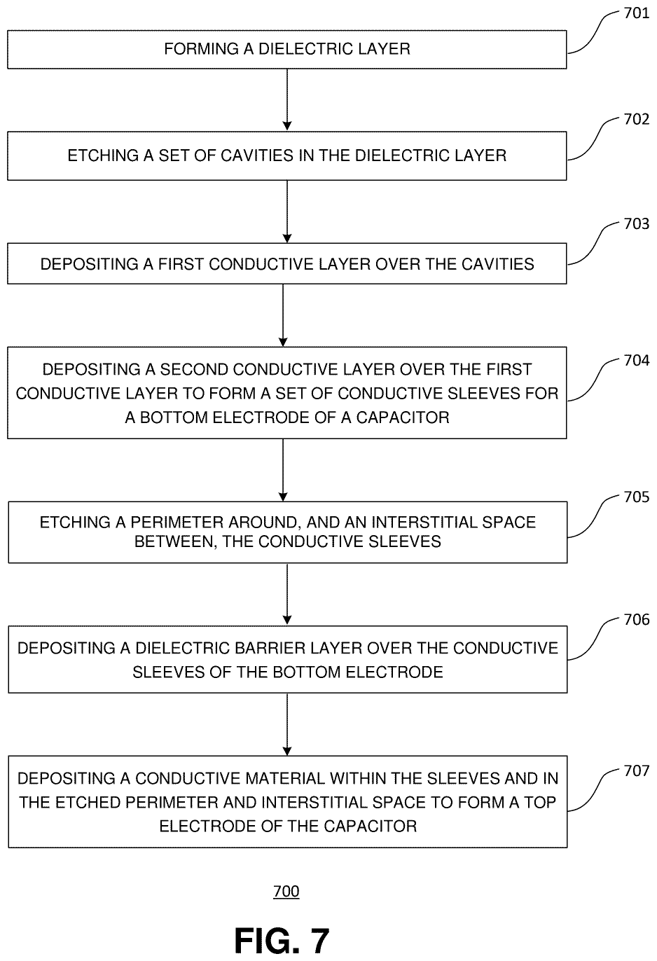

FIG. 7 is a flowchart illustrating a method 700 of forming a 3D MIM capacitor 101 in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. Acts can correspond, for example, to the structures previously illustrated in FIGS. 6A-6Z in some embodiments.

At act 701, a dielectric layer is formed in the BEOL stack of an integrated circuit. FIGS. 6A-6B illustrate a cross-sectional view of some embodiments corresponding to act 701.

At act 702, a set of cavities is etched in the dielectric layer formed in act 701. FIGS. 6C-6D illustrate a top view and a cross-sectional view of some embodiments corresponding to act 702.

At act 703, a first conductive layer is deposited over the cavities formed in act 702. FIGS. 6E-6F illustrate a top view and a cross-sectional view of some embodiments corresponding to act 703.

At act 704, a second conductive layer is deposited over the first conductive layer formed in act 703 to form a set of conductive sleeves for a bottom electrode of the capacitor. FIGS. 6L-6M illustrate a top view and a cross-sectional view of some embodiments corresponding to act 704.

At act 705, a perimeter around, and an interstitial space between, the conductive sleeves formed in act 704 is etched. FIGS. 6Q-6R illustrate a top view and a cross-sectional view of some embodiments corresponding to act 705.

At act 706, a dielectric barrier layer is deposited over the conductive sleeves formed and defined in acts 704 and 705. FIGS. 6S-6T illustrate a top view and a cross-sectional view of some embodiments corresponding to act 706.

At act 707, a conductive material is deposited within the sleeves and in the etched perimeter and interstitial space formed and defined in acts 704-705, and over the dielectric barrier formed in act 706, to form a top electrode of the capacitor. FIGS. 6U-6V illustrate a top view and a cross-sectional view of some embodiments corresponding to act 707.

Note that multiple subsequent steps may be performed to produce a usable working IC device. For example, the wafer comprising the capacitor 101 may be bonded to another IC that contains logic, memory, and/or processing circuits. After the above-described wafer processing is completed, the wafer may be singulated into individual die which correspond to individual ICs.

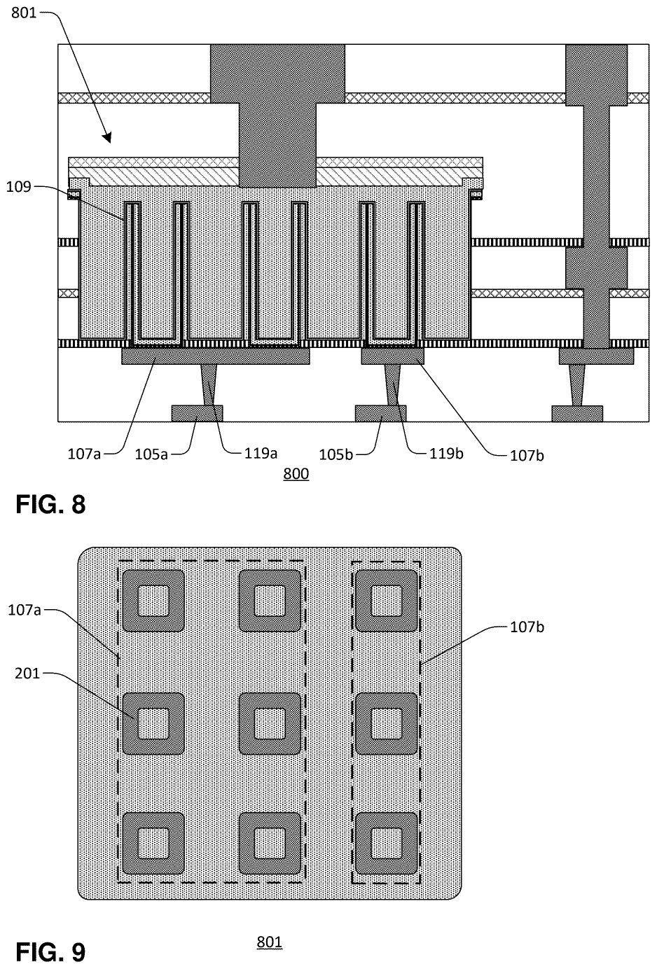

FIG. 8 illustrates a simplified cross-sectional view of an alternative example segment 800 of an IC image sensor, including an example 3D MIM capacitor 801. FIG. 9 illustrates a corresponding simplified partial plan view of the capacitor 801 of FIG. 8. The capacitor 801 is substantially identical to the capacitor 101 of FIG. 1, except that instead of having all of the conductive sleeves 201 of the bottom electrode 109 connect to a single conductive plate 107, some conductive sleeves 201 connect to a first conductive plate 107a while the other conductive sleeves 201 connect to a second conductive plate 107b, different and electrically isolated from the first conductive plate 107a. In the example shown, the first conductive plate 107a is connected to six of the nine conductive sleeves 201 while the second conductive plate 107b is connected to three of the nine conductive sleeves 201. Accordingly, capacitor 801 is functionally a bifurcated capacitor comprising two capacitor segments, where the capacitor segment defined by the larger conductive plate 107a provides a larger capacitance than the capacitor segment defined by the smaller conductive plate 107b. This arrangement may be useful for particular image sensor circuits, as described further below.

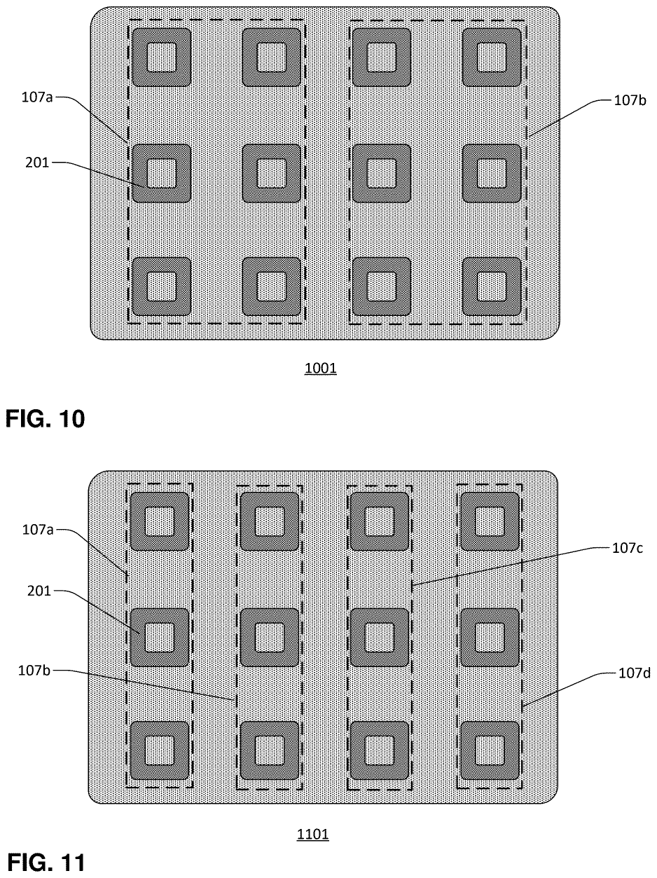

FIG. 10 illustrates a simplified partial plan view of an alternative example 3D MIM capacitor 1001. The capacitor 1001 is substantially similar to the capacitor 801 of FIG. 8, except that (1) the capacitor 1001 has twelve sleeves 201 arranged in a 3×4 array instead of having nine sleeves arranged in a 3×3 array and (2) half of the conductive sleeves 201 connect to the first conductive plate 107a while the other half of the conductive sleeves 201 connect to the second conductive plate 107b, different and electrically isolated from the first conductive plate 107a. Accordingly, capacitor 1001 is functionally a bifurcated capacitor comprising two capacitor segments having the same capacitance. This arrangement may be useful for particular image sensor circuits, as described further below.

FIG. 11 illustrates a simplified partial plan view of an alternative example 3D MIM capacitor 1101. The capacitor 1101 is substantially similar to the capacitor 1001 of FIG. 10, except that a first fourth (a set of three) of the conductive sleeves 201 connect to a first conductive plate 107a, a second fourth of the conductive sleeves 201 connect to a second conductive plate 107b, a third fourth of the conductive sleeves 201 connect to a third conductive plate 107c, and a fourth fourth of the conductive sleeves 201 connect to a fourth conductive plate 107d. The four conductive plates 107a-d are different and electrically isolated from each other. Accordingly, capacitor 1101 is functionally a quadrifurcated capacitor comprising four capacitor segments each having the same capacitance. This arrangement may be useful for particular image sensor circuits, as described further below.

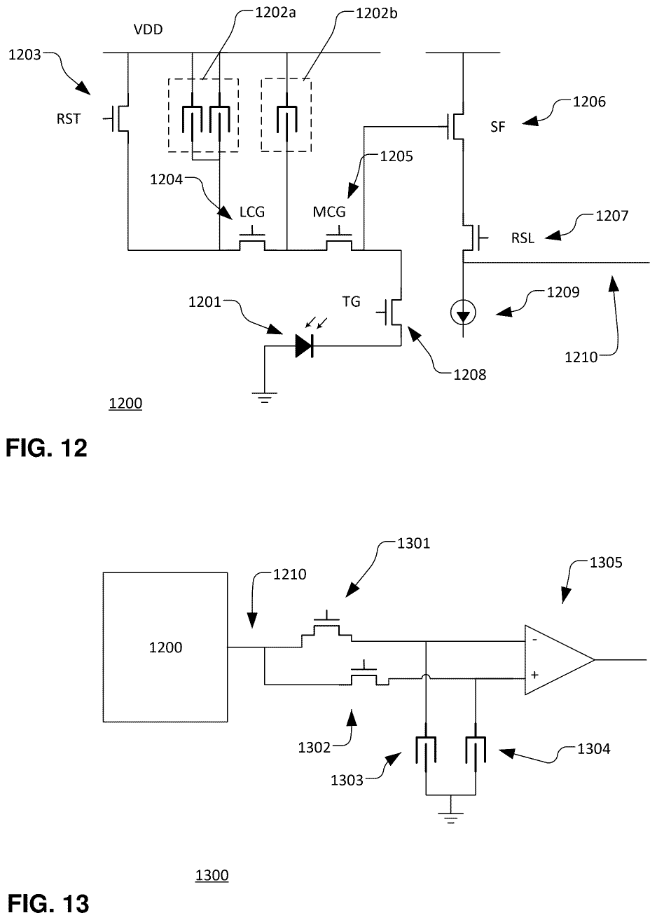

FIG. 12 illustrates a simplified circuit diagram of an example multi-conversion-gain image sensor circuit 1200 in accordance with some embodiments of the disclosure. The circuit 1200 comprises a photodiode 1201, a first capacitor segment 1202a, a second capacitor segment 1202b, transistors 1203, 1204, 1205, 1206, 1207, and 1208, and current source 1209. The capacitor segment 1202a has a larger capacitance than the capacitor segment 1202b and the two segments may correspond to, respectively, the segments connected to the conductive plates 107a and 107b of FIGS. 8 and 9. Transistor 1203 is a reset gate. Transistor 1204 is a low-conversion-gain gate. Transistor 1205 is a middle-conversion-gain gate. Transistor 1206 is a source follower. Transistor 1207 is a row-select gate. Transistor 1208 is a transfer gate. The circuit 1200 may provide an output signal 1210.

The circuit 1200 is configured to optimize a signal to noise ratio for different lighting intensities, which allows for high dynamic range (HDR) imaging. For low light, a high conversion gain is useful and may be achieved by reducing the circuit's capacitance. A minimal capacitance may be achieved by turning off transistors 1204 and 1205. For bright light, a low conversion gain is useful and may be achieved by increasing the circuit's capacitance. A maximal capacitance may be achieved by turning on transistors 1204 and 1205, thereby making available capacitor segments 1202a and 1202b. For intermediate light conditions, a middle conversion gain is useful and may be achieved by turning off transistor 1204 and turning on transistor 1205, thereby making available capacitor segment 1202b.

FIG. 13 illustrates a simplified circuit diagram of an example correlated double sampling (CDS) circuit 1300 in accordance with some embodiments of the disclosure. The CDS circuit 1300 is used to reduce image noise of output 1210 of circuit 1200 of FIG. 12 by subtracting a background output 1210 value from a desired signal output 1210 value. This may be accomplished by using transistors 1301 and 1302 and corresponding capacitor segments 1303 and 1304 to sample and hold a background value (e.g., at reset) and a desired signal value (e.g., following desired exposure) and subtracting the background value from the desired signal value using comparator 1305. The transistor 1301 and capacitor segment 1303 may be said to form part of a background sensing circuit, while the transistor 1302 and capacitor segment 1304 may be said to form part of a signal sensing circuit. The capacitor segments 1303 and 1304 may correspond to, for example, the capacitor segments connected to the identically sized conductive plates 107a and 107b of capacitor 1001 of FIG. 10.

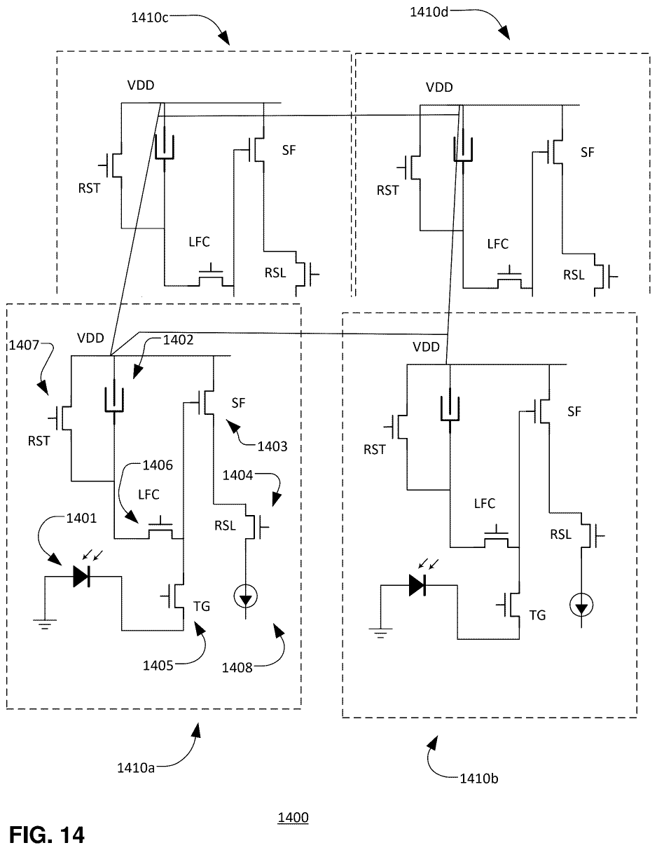

FIG. 14 illustrates a simplified circuit diagram of an example lateral overflow integration capacitor (LOFIC) circuit 1400 in accordance with some embodiments of the disclosure. The LOFIC circuit 1400 may be used for, for example, for small pixels of an image sensor. The LOFIC circuit 1400 comprises four identical sub-circuits 1410a, 1410b, 1410c, and 1410d. Each sub-circuit 1410 comprises a photodiode 1401, a capacitor 1402, a current source 1408, and transistors 1403, 1404, 1405, 1406, and 1407. Transistor 1403 is a source follower. Transistor 1404 is a read select line gate. Transistor 1405 is a transfer gate. Transistor 1406 is a gate for selectively transferring charges to the capacitor 1402. Transistor 1407 is a reset gate.

The top electrodes of the capacitors 1402 of the four sub-circuits are connected together. The capacitor 1402 of each sub-circuit 1410 may correspond to, for example, the capacitor segments connected to the identically sized conductive plates 107a, 107b, 107c, and 107d of the capacitor 1101 of FIG. 11. The rods of the capacitors 1402 may be part of one shared top electrode of the capacitor 1101, while the sleeves correspond to the different bottom electrode conductive plates and corresponding sub-circuits 1410.

Some embodiments relate to a three-dimensional (3D) metal-insulator-metal (MIM) capacitor including: a first electrode having a set of conductive rods, a conductive perimeter, and a conductive filler, all conductively connected to a first conductive plate, and a second electrode comprising a first set of corresponding conductive sleeves conductively connected to a second conductive plate. The first electrode is electrically isolated from the second electrode. For each conductive rod of the first set of conductive rods and corresponding conductive sleeve of the first set of corresponding conductive sleeves: the conductive rod is laterally enveloped by the corresponding conductive sleeve and the conductive rod is electrically isolated from the corresponding conductive sleeve by a dielectric barrier. The conductive perimeter and the conductive filler envelop the first set of corresponding conductive sleeves. The first set of conductive sleeves is electrically isolated from the conductive perimeter and the conductive filler by the dielectric barrier.

Some embodiments relate to an IC image sensor including a multifurcated capacitor having a plurality of segments. Each segment includes a set of conductive rods conductively connected to a first conductive plate and a set of corresponding conductive sleeves conductively connected to a corresponding conductive plate. The capacitor comprises a conductive perimeter and a conductive filler enveloping the sets of corresponding conductive sleeves. The conductive perimeter and conductive filler are conductively connected to the first conductive plate. The first conductive plate is electrically isolated from the corresponding conductive plates. The corresponding conductive plates are electrically isolated from each other. For each conductive rod of the sets of conductive rods and corresponding conductive sleeve of the sets of corresponding conductive sleeves: the conductive rod is laterally enveloped by the corresponding conductive sleeve, the conductive rod is electrically isolated from the corresponding conductive sleeve by a dielectric barrier, and the sets of conductive sleeves are electrically isolated from the conductive perimeter and the conductive filler by the dielectric barrier. Some embodiments relate to a method including: forming a dielectric layer, etching a set of cavities in the dielectric layer, depositing a first conductive layer over the cavities, depositing a second conductive layer over the first conductive layer to form a set of conductive sleeves for a bottom electrode of a capacitor, etching a perimeter around, and an interstitial space between, the conductive sleeves, depositing a dielectric barrier layer over the conductive sleeves of the bottom electrode, and depositing a conductive material within the sleeves and in the etched perimeter and interstitial space to form a top electrode of the capacitor.

Various implementations of image sensors that include an array of pixel elements in accordance with embodiments of the application. It should be noted that alternative implementations may additionally include one or more arrays of conventional pixel elements. For example, an image sensor in accordance with embodiments of the application may comprise (1) a first array of pixel elements each including a capacitor having an area covering more than half of the area of the pixel element and (2) a second array of pixel elements each including no capacitors having an area covering more than half of the area of the pixel element (e.g., using small-area capacitors or having no capacitors at all). In other words, the term “each” refers to each pixel element of the array, not necessarily to each pixel element of the image sensor.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a capacitor comprising:
a first electrode comprising:
a set of conductive rods, a conductive perimeter, and a conductive filler, all conductively connected to a first conductive plate; and
a second electrode comprising a first set of corresponding conductive sleeves conductively connected to a second conductive plate, wherein:
the first electrode is electrically isolated from the second electrode;
for each conductive rod of the first set of conductive rods and corresponding conductive sleeve of the first set of corresponding conductive sleeves:
the conductive rod is laterally enveloped by the corresponding conductive sleeve; and
the conductive rod is electrically isolated from the corresponding conductive sleeve by a dielectric barrier;
the conductive perimeter and the conductive filler envelop the first set of corresponding conductive sleeves; and
the first set of conductive sleeves is electrically isolated from the conductive perimeter and the conductive filler by the dielectric barrier.

2. The device of claim 1, wherein, for each rod of the first set of conductive rods, the rod is substantially uniform and free from dielectric material.

3. The device of claim 1, wherein, for each sleeve of the first set of corresponding conductive sleeves, the sleeve comprises an inner section and an outer section, which are laterally and conductively connected by a diffusion barrier.

4. The device of claim 3, wherein the inner section further comprises a bottom section conductively connected to the second conductive plate via the diffusion barrier.

5. The device of claim 4, wherein the outer section is separated from the second conductive plate by a dielectric layer.

6. The device of claim 1, wherein the capacitor is formed in a set of metallization layers of an integrated circuit (IC) device.

7. The device of claim 6, wherein the set of metallization layers includes metal routing lines, vias, inter-layer dielectric, and one or more etch-stop layers.

8. The device of claim 6, wherein the set of metallization layers includes additional 3D MIM capacitors, vias, and inter-layer dielectric, and is free of etch-stop layers and metal routing lines.

9. The device of claim 1, wherein:
the capacitor is a bifurcated capacitor further comprising:
a second set of conductive rods conductively connected to the first conductive plate; and
a second set of corresponding conductive sleeves conductively connected to a third conductive plate;
the second set of corresponding conductive sleeves are also enveloped by the conductive perimeter and filler; and
the third conductive plate is electrically isolated from the first and the second conductive plates.

10. The device of claim 9, wherein:
the first set of corresponding conductive sleeves is larger than the second set of corresponding conductive sleeves;
the first set of corresponding conductive sleeves is used in a lower conversion gain circuit of a multi-conversion gain circuit of an IC image sensor; and
the second set of corresponding conductive sleeves is used in a higher conversion gain circuit of the multi-conversion gain circuit of the IC image sensor.

11. The device of claim 9, wherein:
the first set of corresponding conductive sleeves is the same size as the second set of corresponding conductive sleeves;
the first set of corresponding conductive sleeves is used in a background sensing circuit of a correlated double sensing (CDS) circuit of an IC image sensor; and
the second set of corresponding conductive sleeves is used in a signal sensing circuit of the CDS circuit of the IC image sensor.

12. The device of claim 9, wherein:
the capacitor is quadrifurcated, further comprising:
a third and a fourth set of conductive rods conductively connected to the first conductive plate; and
a third and a fourth set of corresponding conductive sleeves conductively connected to, respectively, a fourth and a fifth conductive plate;
the third and fourth sets of corresponding conductive sleeves are also enveloped by the conductive perimeter and filler;
the fourth and fifth conductive plates are electrically isolated from the first, second, and third, conductive plates, and from each other; and
each of the first, second, third, and fourth set of corresponding conductive sleeves is used in a corresponding lateral overflow integration capacitor (LOFIC) circuit of an image sensor.

13. A device comprising:
a multifurcated capacitor comprising a plurality of segments, wherein:
each segment comprises:
a set of conductive rods conductively connected to a first conductive plate; and
a set of corresponding conductive sleeves conductively connected to a corresponding conductive plate;
the first conductive plate is electrically isolated from the corresponding conductive plates;
the corresponding conductive plates are electrically isolated from each other;
for each conductive rod of the sets of conductive rods and corresponding conductive sleeve of the sets of corresponding conductive sleeves:
the conductive rod is laterally enveloped by the corresponding conductive sleeve; and
the conductive rod is electrically isolated from the corresponding conductive sleeve by a dielectric barrier.

14. The device of claim 13, wherein:
the device comprises a multi-conversion gain circuit including a low-conversion gain circuit and a middle conversion gain circuit;
the set of corresponding conductive sleeves of a first segment is larger than the set of corresponding conductive sleeves of a second segment;
the set of corresponding conductive sleeves of the first segment is used in the low conversion gain circuit; and
the set of corresponding conductive sleeves of the second segment is used in the middle conversion gain circuit.

15. The device of claim 13, wherein:
the device comprises a correlated double sensing (CDS) circuit having a background sensing circuit and a signal sensing circuit;
the set of corresponding conductive sleeves of a first segment is the same size as the set of corresponding conductive sleeves of a second segment;
the set of corresponding conductive sleeves of the first segment is used in the background sensing circuit; and
the set of corresponding conductive sleeves of the second segment is used in the signal sensing circuit.

16. The device of claim 13, wherein:
the device comprises a plurality of lateral overflow integration capacitor (LOFIC) circuits; and
each capacitor segment is used in a corresponding LOFIC circuit.

17. A method comprising:
forming a dielectric layer;
etching a set of cavities in the dielectric layer;
depositing a first conductive layer over the cavities;
depositing a second conductive layer over the first conductive layer to form a set of conductive sleeves for a bottom electrode of a capacitor;
etching a perimeter around, and an interstitial space between, the conductive sleeves;
depositing a dielectric barrier layer over the conductive sleeves of the bottom electrode; and
depositing a conductive material within the sleeves and in the etched perimeter and interstitial space to form a top electrode of the capacitor.

18. The method of claim 17, further comprising, after depositing the first conductive layer and before depositing the second conductive layer, etching the bottom of the first conductive layer to expose an underlying conductive plate.

19. The method of claim 18, further comprising, after etching the bottom of the first conductive layer and before depositing the second conductive layer, depositing a diffusion barrier layer over the first conductive layer and the exposed underlying conductive plate.

20. The method of claim 19, further comprising, after depositing the conductive material:
depositing additional dielectric layers over the top electrode of the capacitor; and
forming a conductive interconnect to the top electrode through the additional dielectric layers.
